(19) United States
(12) Patent Application Publication
(10) Pub. No.: US 2022/0262990 A1
(43) Pub. Date: Aug. 18, 2022

(54) COMPONENT WITH CORROSION PROTECTION AND METHOD FOR MANUFACTURING A COMPONENT WITH CORROSION PROTECTION

(71) Applicant: OSRAM Opto Semiconductors GmbH, Regensburg (DE)

(72) Inventor: Thomas Reeswinkel, Regensburg (DE)

(21) Appl. No.: 17/616,913

(22) PCT Filed: May 29, 2020
(86) PCT No.: PCT/EP2020/065021

§ 371 Date: Dec. 6, 2021

(30) Foreign Application Priority Data
Jun. 7, 2019 (DE) 10 2019 115 600.9

(51) Int. Cl. H01L 33/56; H01L 33/60; H01L 23/31; H01L 33/62; H01L 23/498; H01L 23/29

(52) U.S. Cl. CPC H01L 33/56; H01L 33/60; H01L 23/3135; H01L 25/0753; H01L 23/49894; H01L 23/296; H01L 33/62

(57) ABSTRACT

In an embodiment an optoelectronic component includes a carrier having a mounting surface including a reflective coating, a semiconductor chip arranged on the carrier and a corrosion protection layer located on the semiconductor chip, the semiconductor chip being arranged in a vertical direction between the reflective coating and the corrosion protection layer, wherein the reflective coating includes a barrier layer disposed in the vertical direction in places between the semiconductor chip and the reflective coating, wherein the barrier layer includes an inorganic material and serves as an additional corrosion protection layer for the reflective coating, wherein the barrier layer has a vertical layer thickness between 1 nm and 100 nm, inclusive, and wherein the corrosion protection layer has a vertical layer thickness between 10 nm and 5000 nm, inclusive.

This patent application is a national phase filing under section 371 of PCT/EP2020/065021, filed May 29, 2020, which claims the priority of German patent application 102019115600.9, filed Jun. 7, 2019, each of which is incorporated herein by reference in its entirety.

### TECHNICAL FIELD

A component, in particular an optoelectronic component, is specified. Further, a method for producing an optoelectronic component is specified.

### BACKGROUND

Carriers for optoelectronic semiconductor chips have a mounting surface on which a component part, in particular an optoelectronic semiconductor chip, or a plurality of component parts is/are arranged. For efficiently reflecting electromagnetic radiation emitted by the optoelectronic semiconductor chip away from the carrier, the mounting surface is preferably provided with a reflective coating, in particular with a silver coating. However, the reflective coating may degrade and change its original color, for example, under the influence of corrosive gases, for example, of H₂S gas, due to corrosion.

For example, a silver coating changes its color under the influence of H₂S gas, for example, from a reflective metallic silver to a darker color. Due to this color change, the reflectivity of a corroded reflective coating decreases. Since the reflectivity changes or degrades differently depending on the wavelength, the chromaticity of the light emitted from the optoelectronic component may be undesirably changed compared to the non-corroded component.

### SUMMARY

Embodiments provide an efficient and color-stable component. Further embodiments provide a reliable and cost-efficient method for producing a component.

According to at least one embodiment of a component, in particular of an optoelectronic component, it comprises a carrier and a component part arranged on the carrier. The component part may be a semiconductor chip, in particular an optoelectronic semiconductor chip. In operation of the component, the semiconductor chip is configured, for example, to generate electromagnetic radiation. The carrier has a mounting surface which is preferably provided with a reflective coating. The component part may be arranged on the reflective coating.

According to at least one embodiment of the component, a corrosion protection layer is formed on the component part, wherein the component part is arranged in a vertical direction between the reflective coating and the corrosion protection layer. In top view, the corrosion protection layer may completely cover the component part. A large part of the reflective coating, for example at least 50%, 60%, 70%, 80% or at least 90% of the reflective coating, may be covered by the corrosion protection layer. It is possible for the reflective coating to be completely covered by the corrosion protection layer in a plane view of the carrier.

A vertical direction is generally understood to mean a direction perpendicular to a main extension surface of the carrier. A lateral direction, on the other hand, is understood to mean a direction which is, in particular, parallel to the main extension surface of the carrier. The vertical direction and the lateral direction are transverse, for instance orthogonal to each other.

According to at least one embodiment of the component, it has a barrier layer which is arranged in the vertical direction at least in places between the component part and the reflective coating. The barrier layer is preferably formed from an inorganic material and can serve as an additional corrosion protection layer for the reflective coating. The barrier layer and the corrosion protection layer may be formed from the same material or from different materials. In particular, the corrosion protection layer is electrically insulating. The barrier layer may be electrically insulating or electrically conductive. Along the vertical direction, the barrier layer is arranged in particular between the corrosion protection layer and the reflective coating. In top view of the carrier, together the barrier layer and the corrosion protection layer may completely cover the reflective coating.

In at least one embodiment of an optoelectronic component, the optoelectronic component comprises a carrier and a semiconductor chip disposed on the carrier. The carrier has a mounting surface that is provided with a reflective coating. A corrosion protection layer is formed on the semiconductor chip, wherein the semiconductor chip is disposed between the reflective coating and the corrosion protection layer in the vertical direction. A barrier layer is provided on the reflective coating, wherein the barrier layer is disposed in the vertical direction in places between the semiconductor chip and the reflective coating. The barrier layer is formed from an inorganic material and serves as an additional corrosion protection layer for the reflective coating. The barrier layer may be arranged between the bonding layer and the reflective coating. In particular, the barrier layer is arranged directly on the reflective coating. In top view, the corrosion protection layer is arranged in particular on the reflective layer covered by the barrier layer and may partially or completely cover the reflective layer.

The corrosion protection layer and the barrier layer are configured to improve in particular the corrosion resistance of the reflective coating. The corrosion protection layer and/or the barrier layer may be formed from a transparent material having a lower gas permeability than a casting material for instance silicone or other casting material. In particular, the barrier layer and/or the corrosion protection layer are/is formed to be gas-impermeable. For example, a vertical layer thickness of the corrosion protection layer and/or the barrier layer is selected such that the corrosion protection layer and/or the barrier layer are/is gas-impermeable.

In particular, the barrier layer has a layer thickness that is between 1 nm and 100 nm inclusive, between 1 nm and 50 nm inclusive, or between 1 nm and 25 nm inclusive. The barrier layer may be applied to the mounting surface of the carrier prior to the attachment of the component part. The corrosion protection layer may have a vertical layer thickness that is, for example, between 10 nm and 5000 nm, inclusive. In particular, the corrosion protection layer is applied to the component part and to the carrier only after the component part has been attached.

Due to the double coverage of the reflective coating by gas-impermeable or nearly gas-impermeable layers, the reflective coating can be effectively protected, in particular, from harmful gases. With regard to mechanical or thermomechanical stresses, for example during processing or soldering of the component, cracks that occur simultaneously or in the same place in both protective layers can be prevented. The risk regarding the penetration of harmful gases at the cracks into the reflective coating can thus be minimized, which improves the long-term corrosion stability of the component.

Since the barrier layer is formed from an inorganic material, the barrier layer can be formed to be particularly gas-tight compared to a protective layer made from an organic material or of organic chemical compounds. For example, the layer thickness of the barrier layer made from an inorganic material can be adjusted in a simple manner using proven coating processes. In addition, the barrier layer can be formed in a particularly conformal manner to possible unevennesses on the mounting surface, in particular at edges and corners of possible metallizations on the mounting surface.

According to at least one embodiment of the component, the barrier layer has a three-dimensional network structure. Thus, the barrier layer is formed in particular as an independent layer. After the formation, such a barrier layer may exist independently of further layers. For example, the barrier layer is formed as a self-supporting layer. A self-supporting layer is understood to mean a layer which is in particular self-supported and does not fall apart under its own weight. However, under the action of its own weight, the self-supporting layer can be deformed.

The three-dimensional network structure may be polysiloxane-like, crystal-like in near-order, or a three-dimensional network of interlinked macromolecules. For example, the barrier layer is formed from an amorphous material. However, in the near-order, especially exclusively in the near-order, the amorphous material of the barrier layer may have a regular three-dimensional network structure. Such a material, however, has no long-range order, i.e., no regular and periodic arrangement of atoms or molecules far from the near-order environment.

Compared to a protective layer made from organic or organic-chemical compounds, for example compared to a thiolate coating described for example in the publication DE 10 2016 111566 A1, the barrier layer of the same layer thickness made from an inorganic material has a significantly lower degree of permeability for common harmful gases. A thiolate coating is formed, for example, by applying a thiol to a surface, thereby forming a monolayer (thiolate) on the surface. Thus, a thiolate coating does not have a three-dimensional network structure but rather a two-dimensional network structure.

This monolayer or a plurality of such monolayers can indeed prevent harmful gas molecules, for example H₂S molecules, from reacting with the surface. However, the monolayers do not form network links in all three spatial directions, so that the monolayers do not form a true barrier layer with a three-dimensional network structure. Thus, the monolayer or the plurality of such monolayers do not form an independent barrier layer especially having a three-dimensional network structure.

Moreover, since the thiols are organic chemical compounds, the thiolate monolayers can often be formed only on specific metals. Unlike a barrier layer made of an inorganic material, the thiolate coating is therefore not universally applicable. In addition, the thiolate coating is only suitable as a protective layer for a small number of harmful gases. In contrast, a gas-impermeable barrier layer made of an inorganic material can find application as a suitable protective layer for a significantly larger number of harmful gases compared to a thiolate coating or to a coating made of organic chemical compounds.

According to at least one embodiment of the component, the inorganic material of the barrier layer and/or the corrosion protection layer is an oxide, nitride, oxynitride, or a fluoride material. It is also possible that the inorganic material of the barrier layer is a siloxane-based, polysiloxane-based, or a polysiloxane-type material.

The barrier layer and/or the corrosion protection layer may comprise one or several inorganic layers and may, for example, comprise a layer stack or layer arrangement. Preferably, the inorganic layer is formed as transparent as possible in the wavelength range of the emitted light of the component part in order not to impair the efficiency of the component or to impair it only as little as possible. Suitable electrically insulating materials for this purpose are, for example, oxides, oxinitrides or nitrides, in particular of one or several elements of the following group comprising: silicon, aluminum, titanium, zinc, indium, tin, niobium, tantalum, hafnium, zirconium, yttrium and germanium. The inorganic layer may be an Al₂O₃ layer, SiO₂ layer, Si₃N₄ layer, TiO₂ layer, ZnO₂ layer, Ta₂O₅ layer, Ge₃N₄ layer, or a ZrO₂ layer.

An inorganic layer of a siloxane-type or polysiloxane-type material may be a layer formed by deposition and by polymerization, in particular by plasma polymerization. For example, the inorganic layer is a plasma-polymerized siloxane layer based in particular on hexamethyldisiloxane, tetramethyldisiloxane or on divinyltetramethyldisiloxane. Such a layer can be produced by a plasma polymerization process under vacuum or atmospheric pressure.

According to at least one embodiment of the component, the barrier layer or the corrosion protection layer is an electrically insulating layer. However, it is possible that the inorganic material of the barrier layer is a radiation-transmissive and electrically conductive material. For example, the barrier layer is formed from a transparent electrically conductive oxide.

Transparent conductive oxides (TCO) are transparent and conductive materials, usually metal oxides, for instance zinc oxide, tin oxide, cadmium oxide, titanium oxide, indium oxide, or indium tin oxide (ITO). In addition to binary metal oxygen compounds, for instance ZnO, SnO₂ or In₂O₃, ternary metal oxygen compounds, for instance Zn₂SnO₄, CdSnO₃, ZnSnO₃, MgIn₂O₄, GaInO₃, Zn₂In₂O₅ or In₄Sn₃O₁₂ or mixtures of different transparent conductive oxides also belong to the group of TCOs. Furthermore, the TCOs do not necessarily correspond to a stoichiometric composition and may also be p-doped or n-doped.

According to at least one embodiment of the component, the vertical layer thickness of the corrosion protection layer is equal to or greater than, for example, at least two times, at least three times, at least five times, at least ten times or at least 20 times greater than the vertical layer thickness of the barrier layer. However, it is conceivable that the vertical layer thickness of the corrosion protection layer has a smaller layer thickness than the barrier layer.

The vertical layer thickness of the barrier layer may be between 1 nm and 100 nm inclusive, between 1 nm and 25 nm inclusive, or between 1 nm and 10 nm inclusive, for instance between 1 nm and 5 nm, for example between 1 nm and 3 nm. Using such a thin barrier layer, the barrier layer can be easily penetrated to establish an electrical connection between the component part or between the semiconductor chip and the carrier. In addition, the thin barrier layer has a particularly high conformity with the environment, so that the reflective coating is sealed in a particularly gas-tight manner by the barrier layer. However, it is possible for the barrier layer to have a layer thickness greater than 100 nm or greater than 200 nm. For example, the barrier layer may be formed from MgF₂.

For example, the barrier layer is applied to the mounting surface by a sputtering process, a plasma-enhanced chemical vapor deposition (PECVD) process, or by an atomic layer deposition (ALD) process. Atomic layer deposition is especially suitable for producing a particularly thin barrier layer with a particularly high conformity with the environment.

The vertical layer thickness of the corrosion protection layer may be between 10 nm and 5000 nm inclusive, for example between 10 nm and 1000 nm inclusive, between 10 nm and 500 nm inclusive, or between 10 nm and 200 nm inclusive. The corrosion protection layer may be formed using the same process and/or material as the barrier layer. However, since greater layer thicknesses are also desired for the corrosion protection layer and, as a result, quite such a high level of conformity is also not required, other processes and materials can also be used for the formation of the corrosion protection layer under other aspects for instance, for example, throughput, costs, efficiency.

According to at least one embodiment of the component, the component part or the semiconductor chip is electrically conductively connected to the carrier via at least one electrical connection structure or via a plurality of electrical connection structures. In particular, the electrical connection structure extends along the vertical direction throughout the barrier layer to the mounting surface. In particular, the barrier layer is electrically insulating. If the barrier layer is electrically conductive, it is alternatively possible for the connection structure to terminate on the barrier layer and be electrically conductively connected thereto.

The connection structure can be a wire connection, for instance a bonding wire or a conductor track, or a connection column, or can be an electrically conductive adhesive or an electrically conductive connection material as a connection layer. It is possible for the connection structures to be located exclusively on a front side facing away from the mounting surface, exclusively on a rear side facing the mounting surface, or partially on the front side and partially on the rear side of the component part or semiconductor chip. In other words, the component part or the semiconductor chip may be externally electrically contactable exclusively via its front side, exclusively via its rear side, or partially via the front side and partially via the rear side. The connection structure may be indirectly or directly adjacent to the barrier layer.

According to at least one embodiment of the component, the carrier is part of a housing, wherein the carrier is laterally enclosed by a non-metallic housing frame. The housing frame may have a cavity, on a bottom surface of which the component part or semiconductor chip is arranged. The cavity may have a circumferential lateral surface that may be covered by the barrier layer. The lateral surface may be partially or completely covered by the barrier layer.

For example, the carrier is in the form of a lead frame. The carrier may have a first subsection assigned to, for example, a first electrode of the component, and a second subsection assigned to, for example, a second electrode, wherein the first subsection is spaced apart from the second subsection in the lateral direction. In particular, the first subsection is mechanically connected to the second subsection via the housing frame. Along the vertical direction, the first and/or second subsection may extend throughout the housing frame. In particular, the housing frame is electrically insulating and may be an encapsulation. The mounting surface of the component may be formed by surface/s of the first subsection and/or of the second subsection.

According to at least one embodiment of the component, the semiconductor chip is configured to generate electromagnetic radiation, for example in the infrared, visible or ultraviolet spectral range, during operation of the component. In particular, the semiconductor chip is a volume emitter. In the case of a volume emitter, electromagnetic radiation generated during operation of the semiconductor chip can be coupled out not only via the front side, but also via the rear side and via the side surfaces of the semiconductor chip.

According to at least one embodiment of the component, the semiconductor chip is attached to the barrier layer by a bonding layer. In particular, the bonding layer is electrically insulating. The bonding layer may be an adhesive layer. For example, the bonding layer has reflective particles for reflecting electromagnetic radiation, particles for improving thermal conductivity or electrically conductive particles. The thermally conductive particles or the reflective particles may be embedded in a matrix material, in particular in an adhesive matrix material, of the bonding layer. It is also possible that the bonding layer is free of reflective particles and/or free of additional particles for improving thermal conductivity. It is also conceivable that the bonding layer is made of an adhesive filled with electrically conductive particles, e.g. silver particles, for additional electrically connecting purposes.

According to at least one embodiment of the component, the corrosion protection layer and the barrier layer are formed from the same material. The corrosion protection layer and the barrier layer may be formed successively by the same manufacturing process. In particular, the barrier layer is applied to the reflective coating before the semiconductor chip is attached. In particular, the corrosion protection layer may be applied to the semiconductor chip and/or to the barrier layer after the semiconductor chip has been attached. Deviating therefrom, it is possible that the corrosion protection layer and the barrier layer are formed from different materials or are produced by different manufacturing processes.

According to at least one embodiment of the component, the reflective coating is a silver coating. The semiconductor chip is a volume emitter attached to the barrier layer by the bonding layer. The bonding layer may have an adhesive matrix material in which reflective particles or thermal conduction particles are embedded. However, in deviation from a silver coating, another coating, in particular a metallic coating, for instance aluminum or gold coating, can be used, or a coating made of an alloy, in particular a silver-based alloy.

A silver coating, however, is preferred since in addition to the electrical and thermal bonding of the component part, silver has a very high reflectivity for the visible light spectrum and thus increases the brightness or efficiency of the component. This can be particularly a key factor for designs with bonded volume emitter chips, since a large proportion of the light generated by a volume emitter hits the reflective coating. Since silver is very sensitive to corrosion, especially to corrosive gases for instance H₂S, the reflective coating can quickly turn dark or black under normal conditions. As a result, less light is reflected. In addition, the reflection is wavelength-dependent due to the discoloration. The component therefore shines darker and in a altered light color.

For preventing the corrosion of the reflective coating, the component has a corrosion protection layer and a barrier layer, wherein the barrier layer serves as an additional corrosion protection layer. In addition, the component may have an encapsulation which, in top view, covers the semiconductor chip in particular completely. The encapsulation is formed in particular for encapsulating the semiconductor chip and can be a silicone encapsulation or an epoxy resin encapsulation or a hybrid material. Since silicones are much more light-stable and do not age as rapidly as epoxy resins, silicones are preferred over epoxy resins. The matrix material of the bonding layer can also be formed from a silicone. A combination of the encapsulation, the corrosion protection layer and the barrier layer can protect the reflective coating from possible corrosion particularly well, since the encapsulation, the corrosion protection layer and the barrier layer can be formed from different materials and can thus be particularly effective in preventing different harmful gases from penetrating into the reflective coating.

According to at least one embodiment of the component, the barrier layer is electrically insulating. The semiconductor chip can be electrically conductively connected to the carrier via electrical connection structures, wherein the electrical connection structures extend along the vertical direction throughout the barrier layer and can be indirectly or directly adjacent to the barrier layer. However, if the barrier layer is formed to be electrically conductive, the electrical connection structures may be arranged on the barrier layer and, in particular, may be in direct electrical contact with the barrier layer.

According to at least one embodiment of the component, it comprises an electronic component part. The component part may be a further optoelectronic semiconductor chip, a protective diode, for instance an ESD chip (electrostatic discharge chip) or an IC chip (integrated circuit chip). In particular, the component part is electrically conductively connected to the semiconductor chip. For example, the component part is arranged on the barrier layer, wherein the component part is covered, in particular completely covered, by the corrosion protection layer in top view. The component may comprise a plurality of component parts, for example in the form of light-emitting semiconductor chips, light-detecting semiconductor chips, protective diodes and/or IC chips. It is also possible for a component part to include multiple electronic elements for instance optoelectronic semiconductor chips, ESD chips, or IC chips. Non-light emitting or detecting chips for instance ESD chip, IC chip may also well be enclosed within the housing. For example, they may be enclosed/covered during injection molding around the lead frame or during the formation of a cavity, for instance by potting/dispensing a silicone ring.

In one embodiment of a light source, it comprises a component, in particular a component described herein, wherein the component part or semiconductor chip is configured to generate electromagnetic radiation in the visible, infrared or ultraviolet spectral range during operation of the component. The light source can be used in general lighting, in a vehicle, for instance in exterior and interior lighting of a vehicle, or in a headlight of a vehicle. It is also conceivable that the light source or component may find application in electronic devices, cell phones, touchpads, laser printers, cameras, recognition cameras, displays, or in systems comprising LEDs, sensors, laser diodes, and/or detectors.

In at least one embodiment of a method for producing an optoelectronic component, a carrier is provided. The carrier has a mounting surface which in particular is provided with a reflective coating. A barrier layer is applied to the reflective coating, wherein the barrier layer is formed from an inorganic material. Preferably, the barrier layer serves as an additional corrosion protection layer for the reflective coating. In particular, after the barrier layer has been applied, a semiconductor chip is attached to the carrier. For example, the semiconductor chip is bonded to the carrier by a bonding layer. In particular, after the semiconductor chip has been attached, a corrosion protection layer is applied to the semiconductor chip. The semiconductor chip is disposed in the vertical direction between the reflective coating and the corrosion protection layer. The barrier layer is arranged in the vertical direction at least in places between the semiconductor chip and the reflective coating.

In particular, the corrosion protection layer is applied to the semiconductor chip and/or to the surrounding surfaces of the reflection layer only after all electrical contacts of the semiconductor chip have been made. The surface protection provided by the corrosion protection layer can generally be quite good. However, if the corrosion protection layer is a thin, hard or brittle protective layer, it may be susceptible to mechanical or thermomechanical stresses, creating possible cracks in the corrosion protection layer, allowing harmful gases to diffuse through. Possible cracks are particularly critical at material transitions, especially at an interface with the soft, for example silicone-based bonding layer. The barrier layer, which serves as an additional corrosion protection layer and is arranged between the reflective coating and the corrosion protection layer, can protect the reflective coating from harmful gases particularly effectively.

According to at least one embodiment of the method, the barrier layer is applied to the reflective coating by atomic layer deposition or by a coating process before the semiconductor chip is attached such that the barrier layer is formed as an independent layer on the reflective coating. Since the barrier layer is deposited before the semiconductor chip or the component part is attached or bonded, areas below the semiconductor chip or the component part, i.e., areas between the semiconductor chip or the component part and the reflective coating, can also be protected from corrosion.

For example, after bonding, the component part is electrically contacted, in particular electrically wire-contacted. The component part may be an optoelectronic semiconductor chip, an ESD chip or an IC chip. To facilitate wire-contacting of the component part, the barrier layer can be formed to be particularly thin, since a layer which is too thick would prevent wire-contacting or at least makes it significantly more difficult. Using a thin layer thickness of less than 25 nm, less than 20 nm, in particular less than 10 nm, for example between 1 nm and 5 nm inclusive or between 1 nm and 3 nm inclusive, the formation of a stable electrical contact between the component part and the carrier throughout the barrier layer can be carried out without great effort. In order to achieve sufficient protection at such a low layer thickness, the barrier layer is formed to be as conformal and dense as possible, so that the barrier layer is formed to be impermeable to gases, especially to harmful gases for instance H₂S. By applying appropriate deposition methods for instance atomic layer deposition, PECVD or cathode sputtering, the layer thickness can be adjusted very precisely, irrespective of the material system or of the layer material. In contrast, the adjustment of the layer thickness for a thiolate coating is much more difficult, since the layer thickness of the thiolate coating is given by the material, in particular by the molecule length.

Depending on the design of the carrier, wire thickness, wire material and material of the barrier layer, the electrical contacting, for instance wire-contacting, can also penetrate throughout thicker layers. The barrier layer can be formed thicker than 10 nm, 25 nm, 50 nm or thicker than 100 nm. Component parts for instance LED chips, protective diodes or other chips having integrated circuits are then bonded and wire-contacted throughout the barrier layer. A sufficiently thin barrier layer breaks easily during wire-contacting and thus enables sufficiently good electrical contact.

If a highly conformal deposition process, for instance ALD, is used, the rear side of the component or carrier, and thus the soldering surface, can also be at least partially coated. It has already been shown that if the layer is sufficiently thin, it is detached from the solder or from the soldering flux during the soldering process and the soldering process is not significantly impaired.

Due to the low thickness of the barrier layer, the surface protection may not yet be sufficient for instance for higher corrosion protection requirements. In addition, during wire-contacting, the protection in the area of the wire-contact may be weakened, making a second coating possibly necessary depending on corrosion stability requirements. Therefore, after wire-contacting the component parts, the corrosion protection layer can be applied to the component parts and/or to the mounting surface. With such a coating, even better corrosion protection can be achieved. Subsequently, the component, in particular the LED component, can be further processed, for example with a silicone encapsulation, conversion steps or the like, up to the finished, singulated component.

According to at least one embodiment of the process, the barrier layer is formed in a structured manner such that the reflective coating has subregions that are not covered by the barrier layer in top view. In particular, the semiconductor chip is electrically conductively connected to the carrier at the non-covered subregions.

According to at least one embodiment of the method, the carrier is formed as part of a housing and is laterally enclosed by a non-metallic housing frame. The housing frame can be formed by a casting process or a plastic casting process. In particular, the housing frame has a cavity for receiving the component part or the semiconductor chip. In particular, the barrier layer is applied to the reflective coating and/or to a circumferential lateral surface of the cavity after the housing frame has been formed so that the lateral surface is covered by the barrier layer.

The term “casting process” or “plastic casting process” is generally understood to mean a process by which a molding/casting compound, in this case the housing frame, is formed according to a predetermined shape, preferably under the action of pressure, and, if necessary, cured. In particular, the term “casting process” or “plastic casting process” includes at least dispensing, jet dispensing, molding, injection molding, transfer molding and compression molding.

According to at least one embodiment, the barrier layer is applied to the bottom surface and/or the lateral surface of the cavity after the formation of the housing frame. The barrier layer can be applied over the entire surface of the bottom surface of the cavity and, if necessary, structured in a subsequent process step. Alternatively, it is possible that a mask is used during the application of the barrier layer, so that the barrier layer is applied to the bottom surface of the cavity in a structured manner. Thus, the barrier layer is applied before the semiconductor chip is attached on the mounting surface and thus before the semiconductor chip is electrically contacted.

Alternatively, it is possible that the barrier layer is applied to the reflective coating before the housing frame is formed. The barrier layer may be enclosed by the housing frame in places after the housing frame is formed. In other words, the formation of the barrier layer can be performed prior to the casting or plastic casting process, in particular after the reflective coating, especially the reflective silver layer, is deposited on the mounting surface. In this way, a further weak point, namely the transition of the coating material, in particular of silver, to the molded housing, can be mitigated. Indeed, such a transition can potentially be torn open during further process control of the component if the barrier layer is coated only after the casting or plastic casting process.

In addition, this gives rise to the further possibility that the barrier layer is formed as an electrically conductive transparent layer. Accordingly, the barrier layer can be formed such that after the casting or plastic casting process it survives, for example, the deflashing process undamaged. The barrier layer can be patterned for facilitating the electrical contacting of the ESD chip or of other chips for instance by using an electrically conductive adhesive bonding layer, for instance a silver conductive adhesive layer. Such structuring can be realized before the barrier layer is formed, for example, by using a lacquer layer or by subsequent local removal of the barrier layer. Local removal is carried out, for example, by laser ablation, ion bombardment or similar processes, or also mechanically, for example, by rubbing, milling, stamping or the like.

In principle, structuring can also be carried out in the area of the electrical contacts, for example for simplifying wire-contacting. However, the charm of a thin and, in particular, conformal coating lies precisely in the fact that the latter is not necessary. If a connection structure penetrates throughout the barrier layer, the connection structure can be directly adjacent to the barrier layer. The connection structure may be a bonding wire or a connection column. The component may have a plurality of such connection structures. To improve the layer adhesion, a surface pre-treatment or a surface cleaning can be carried out, for example by a plasma treatment, prior to the deposition of the barrier layer or of the corrosion protection layer or prior to the deposition of these two layers.

Using the barrier layer and the corrosion protection layer, the component can be exposed to harsher corrosion conditions. With the aid of such coatings, substrates coated with silver can be used in particular for LED components for application in corrosive environments, for example, or thus for a wider range of applications. Coating with silver is significantly less expensive than with gold, for example, and also leads to significantly more efficient components due to the higher reflectivity. Furthermore, this enables the use of volume emitter chips with further cost and efficiency advantages.

Compared to a single coating exclusively after electrical contacting of the component parts, the area under the component parts and/or under the bonding layer can also be better protected here, namely both from corrosion by harmful gases and from aging due to moisture and due to contact with the adhesive of the bonding layer. In addition, the material of the barrier layer can be selected or optimized with regard to adhesion, for example to the silver-coated carrier, due to its low thickness, without the need to give great consideration to efficiency losses, which is a limiting secondary condition in the case of a thicker coating exclusively after electrical contacting. The coating mentioned here also protects, for example, silver-coated carriers or silver bonding wires from discoloration, especially when using highly phenylated or HRI silicones for casting. The latter offer the advantage of higher brightness or increased component efficiency.

The method described above is particularly suitable for the production of a component described herein. The features described in connection with the component can therefore also be used for the method, and vice versa.

### BRIEF DESCRIPTION OF THE DRAWINGS

Further advantages, preferred embodiments and further developments of the component or of the method will become apparent from the exemplary embodiments explained below in connection with FIGS. 1A to 4.

FIGS. 1A, 1B and 1C show schematic representations of some exemplary embodiments of a component;

FIGS. 2A, 2B, 2C and 2D show schematic representations of some further exemplary embodiments of a component; and

FIGS. 3 and 4 show schematic representations of further exemplary embodiments of a component having several component parts.

Identical, equivalent or equivalently acting elements are indicated with the same reference numerals in the figures. The figures are schematic illustrations and thus not necessarily true to scale. Comparatively small elements and particularly layer thicknesses can rather be illustrated exaggeratedly large for the purpose of better clarification.

### DETAILED DESCRIPTION OF ILLUSTRATIVE EMBODIMENTS

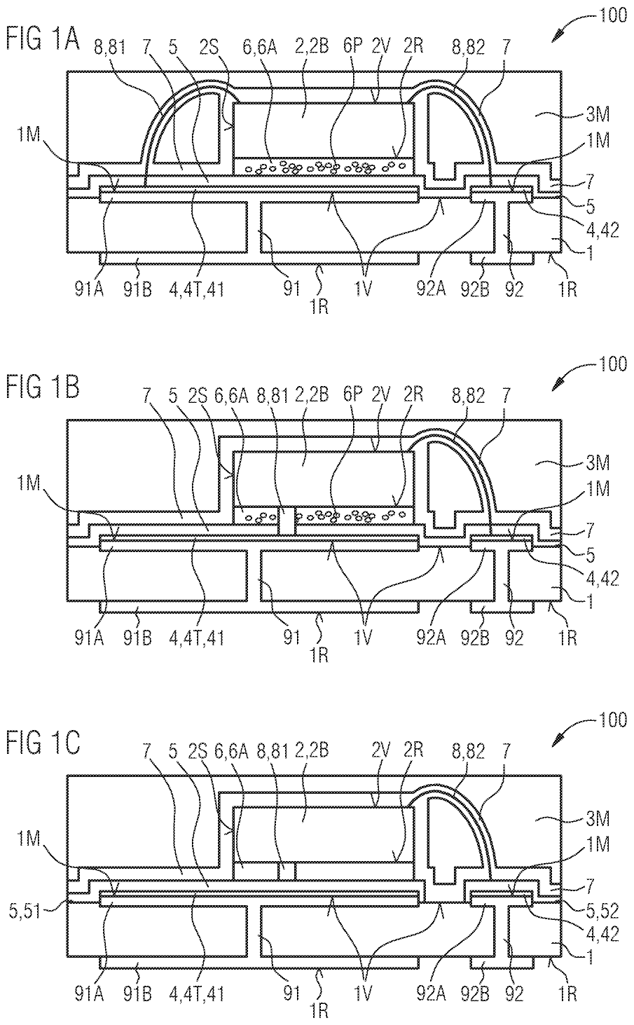

FIG. 1A schematically shows a side view of an optoelectronic component 100. The optoelectronic component 100 is, for example, a light-emitting diode component.

The component 100 comprises a carrier 1, which comprises, for example, an electrically insulating base body, for instance a ceramic substrate. The carrier 1 has a front side 1V and a rear side 1R opposite to the front side 1V. For example, the front side 1V is formed in places by surfaces of a first metallization 91A and a second metallization 92A. The front side 1V may be formed in places by surfaces of the base body of the carrier 1.

The metallizations 91A and 92A are in particular electrically insulated from each other and are arranged on the base body of the carrier 1. A third metallization 91B and a fourth metallization 92B, which are electrically insulated from each other, are located on the rear side 1R of the carrier 1. In particular, the metallizations 91A and 92A on the front side 1V and the corresponding metallizations 91B and 92B on the rear side 1R are electrically conductively connected to each other via through-contacts 91 and 92. The through-contacts 91 and 92 extend along the vertical direction in particular throughout the base body of the carrier 1.

The surfaces of the metallizations 91A and 92A may form a mounting surface 1M of the carrier 1. The front side 1V of the carrier 1 thus forms the mounting surface 1M for electronic component parts 2 and 2B, for example for an optoelectronic semiconductor chip 2. The metallization 91A is provided with a reflective coating 4. That is, the mounting surface 1M is coated with the reflective coating 4. The further metallization 92A may also be provided with the reflective coating 4. For example, the reflective coating 4 is a silver layer or a reflective layer containing silver. Deviating from FIG. 1A, it is possible that the metallizations 91A and 92A are themselves reflective layers, for instance silver-coated reflective layers or silver-containing reflective layers.

The component part 2 or 2B, which may be a light emitting semiconductor chip 2, has a front side 2V and a rear side 2R opposite to the front side 2V. During operation of the component 100, the component part 2 is particularly configured to generate electromagnetic radiation. The component part 2 is arranged with its rear side 2R on the mounting surface 1M. For example, the component part 2 is fixed to the mounting surface 1M by a bonding layer 6, in particular bonded to the mounting surface 1M by an adhesive bonding layer 6.

The bonding layer 6 has a matrix material 6A, in particular an adhesion-promoting matrix material 6A. Reflective particles 6P may be embedded in the matrix material 6A, which are particularly configured to reflect electromagnetic radiation emitted from the component part 2 during operation of the component 100. Thus, between the rear side 2R of the semiconductor chip 2 and the front side of the reflective coating 4, a bonding layer 6 is arranged, which in particular is made of an adhesive. The adhesive may include one or several of: silicone- or siloxane-based materials, silicone epoxy, epoxy, and acrylate. The rear side 2R of the semiconductor chip 2 may be completely covered by the bonding layer 6.

The reflective particles 6P may be formed as white reflective particles. Thus, the reflective particles 6P cause a white color impression. White reflective particles are characterized in particular by the fact that they particularly efficiently reflect emitted electromagnetic radiation and do not change the color location of the emitted electromagnetic radiation.

A barrier layer 5 is arranged between the bonding layer 6 and the reflective coating 4. The barrier layer 5 may be in direct contact with the reflective coating 4 and/or with the bonding layer 6. The reflective coating 4 may be partially or completely covered by the barrier layer 5, or completely covered except for the electrical contact points. It is possible for the bonding layer 6 to be directly adjacent to the barrier layer 5 as well as directly adjacent to the rear side 2R of the component part 2.

As shown schematically in FIG. 1A, the component part 2 or the semiconductor chip 2 is electrically conductively connected to the carrier 1, in particular to the metallizations 91A and 92B, by two connection structures 8, for example in the form of bonding wires 8, on its front side 2V. A first bonding wire 81, for example, forms an electrical connection between a first electrical chip contact area, not shown here, on the front side 2V of the semiconductor chip 2 and the first metallization 91A. A second bonding wire 82 may form an electrical connection between a second electrical chip contact area on the front side 2V of the semiconductor chip 2, not shown here, and the second metallization 92A. The bonding wires 8 may be in direct electrical contact with the subregions 4T of the reflective coating 4.

In particular, the reflective coating 4 is divided into a first subregion 41 and a second subregion 42 spatially separated from the first subregion 41. In a top view of the carrier 1, the first subregion 41 is partially covered in particular by the semiconductor chip 2 and by the bonding layer 6. The second subregion 42 is electrically insulated from the first subregion 41 and may be free from being covered by the semiconductor chip 2 and/or by the bonding layer 6. It is possible that the first subregion 41 covers, in particular completely covers, the first metallization 91A in top view. The second subregion 42 may partially or completely cover the second metallization 92A in top view.

In FIG. 1A, a corrosion protection layer 7, in particular in the form of an inorganic coating, is arranged on the semiconductor chip 2 and on the barrier layer 5. In a top view of the carrier 1, the corrosion protection layer 7 may partially or completely cover exposed surfaces of the carrier 1, exposed surfaces of the metallizations 91A and 92A and/or of the base body of the carrier 1, exposed surfaces of the reflective coating 4, of the semiconductor chip 2 and/or of the connection structures 8. For example, the front side 1V and the side flanks 2S of the semiconductor chip 2 are partially or completely covered by the corrosion protection layer 7.

Even if the corrosion protection layer 7 is formed in the region of the interface between the bonding layer 6 and the corrosion protection layer 7 or in other areas, the barrier layer 5 is still available as additional corrosion protection for the reflective coating 4. This has the effect that preferably all subregions 4T of the reflective coating 4, in particular also the subregion below the semiconductor chip 2, are efficiently protected against corrosion. In a top view of the carrier 1, in particular at any places, the reflective coating 4 is protected against corrosion by both the barrier layer 5 and the corrosion protection layer 7.

According to FIG. 1A, an encapsulation 3M is formed such that, in a top view of the carrier 1, it covers, in particular completely covers, the corrosion protection layer 7, the semiconductor chip 2, the barrier layer 5 and the carrier 1. The semiconductor chip 2 and the connection structures 8 are encapsulated by the encapsulation 3M and are thus partially embedded in the encapsulation 3M. In particular, the encapsulation 3M is formed from a radiation-transmitting material, in particular from a transparent material. For example, the encapsulation 3M is formed with respect to its layer thickness and the material selection such that it is transparent for a large part, for example for at least 50%, 60%, 70%, 80% or for at least 90% of the electromagnetic radiation emitted by the semiconductor chip 2, in particular in the visible, ultraviolet or infrared spectral range.

The encapsulation 3M may comprise an epoxy resin, polysiloxane, silicone or a hybrid material containing silicone. It is also possible for the encapsulation 3M to contain a silicone material, polysiloxane, epoxy resin, or silicone-containing hybrid material filled with particles for instance phosphor particles, scattering materials, or other particles. In the exemplary embodiment shown in FIG. 1A, the encapsulation 3M has a rectangular shape. It is possible for the encapsulation 3M to have a different geometry, for instance a geometry having a dome-like shape.

Deviating from FIG. 1A, the carrier 1 may be in the form of a printed circuit board. The metallizations 91A and 92A can be formed as conductor tracks or connection surfaces. Alternatively, the carrier 1 may be formed from a metallic lead frame which is laterally enclosed, in particular, by an electrically insulating material of the base body of the carrier 1. In this case, the lead frame may be formed by metallizations 91A, 92A, 91B and/or 92B.

The exemplary embodiment illustrated in FIG. 1B is substantially the same as the exemplary embodiment of a component 100 illustrated in FIG. 1A. In contrast, the component part 2 or 2B has only a single bonding wire 82. For electrical contacting of the component part 2 or 2B, there is, in addition to the bonding wire 81, a rear-side connection structure 8, in particular in the form of a rear-side connection column 81. The rear-side connection column 81 extends in particular throughout the barrier layer 5 and forms a direct electrical contact in particular with the reflective coating 4.

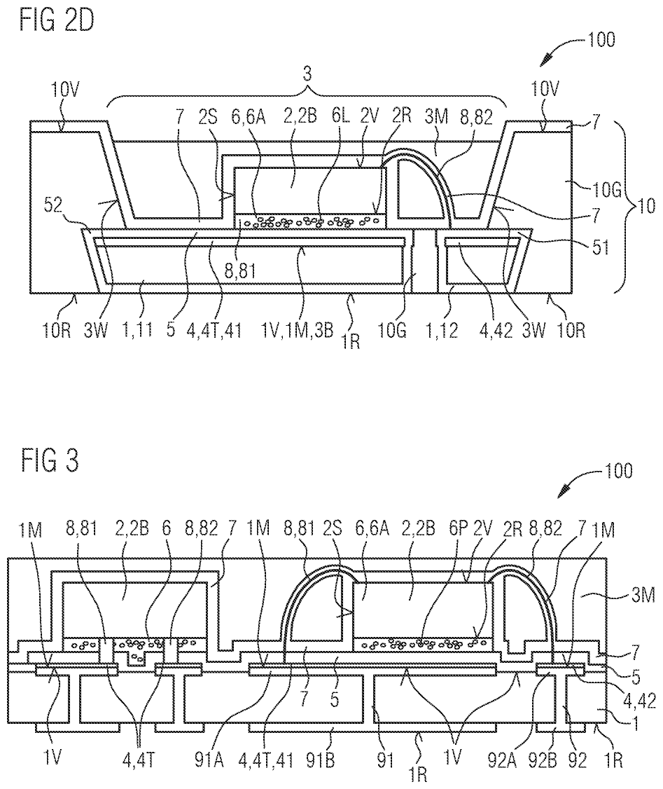

Deviating from FIG. 1B, it is possible for the component part 2 or 2B to have two rear-side connection structures 81 and 82 each in the form of a connection column. The component part 2 may be arranged on the carrier 1 such that one of the connection structures is electrically conductively connected to a first subregion 41 of the reflective coating 4 and the other of the two connection structures is electrically conductively connected to a second subregion 42 of the reflective coating 4. The electrical contacting of such a component part 2 or 2B is shown schematically in FIG. 3, for example.

The exemplary embodiment illustrated in FIG. 1C corresponds substantially to the exemplary embodiment of a component 100 illustrated in FIG. 1B. In contrast thereto, the barrier layer 5 may be formed to be electrically conductive. For example, the barrier layer 5 is formed from a transparent electrically conductive material. In contrast to the exemplary embodiments shown in FIGS. 1A and 1B, the barrier layer 5 is not formed in a contiguous manner, but has at least two subregions 51 and 52 that are laterally separated from each other and thus are spatially and electrically separated. The subregions 51 and 52 of the barrier layer 5 are electrically conductively connected, in particular directly electrically conductively connected, to the subregions 41 and 42 of the reflective coating 4, respectively.

As shown in FIG. 1C, the connection structures 8 end on the respective subregions 51 and 52 of the barrier layer 5. The rear-side connection column 81 and the bonding wire 82 in particular do not extend throughout the barrier layer 5, but end on the barrier layer 5. In an intermediate region between the partial layers 51 and 52 of the barrier layer 5 and in an intermediate region between the partial layers 41 and 42 of the reflective coating 4, respectively, the corrosion protection layer 7 can extend along the vertical direction throughout the barrier layer 5 and/or throughout the reflective coating 4.

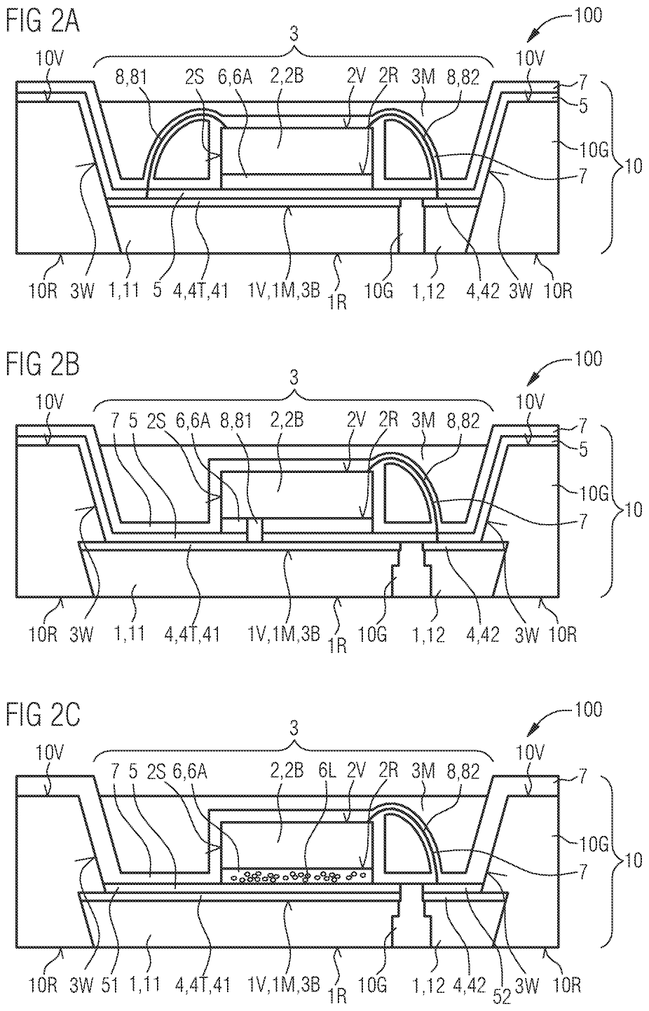

The exemplary embodiment illustrated in FIG. 2A is substantially the same as the exemplary embodiment of a component 100 illustrated in FIG. 1A. In contrast, the carrier 1 is in the form of a lead frame having a first subsection 11 and the second subsection 12, wherein the lead frame is laterally enclosed by a housing frame 10G. The subsections 11 and 12 may be formed by the metallizations 91A and 92A shown in FIGS. 1A to 1C.

The optoelectronic component 100 thus comprises a housing 10 in particular formed by the housing frame 10G and the carrier 1 in particular formed as a lead frame. The housing 10 has a front side 10V and a rear side 10R opposite to the front side 10V. The housing frame 10G has, for example, an electrically insulating plastic material, for example a casting or encapsulating material for instance an epoxy resin or a ceramic material. The housing frame 10G may be formed by a casting or plastic casting process. The lead frame 1 comprises an electrically conductive material, for instance a metal. In particular, the lead frame 1 comprises copper. Copper offers the advantage of being highly electrically as well as thermally conductive.

The subsections 11 and 12 of the carrier 1 can be at least partially, in particular completely, coated with the reflective coating 4, for example with a silver coating. The reflective coating 4 has subregions 4T, 41 and 42 which are electrically spatially and electrically separated from one another and are each electrically conductively connected to one of the subsections 11 and 12 of the carrier 1. The front side 1V of the carrier 1 may be partially or completely covered by the reflective coating 4.

According to FIG. 2A, the subsections 11, 12 of the carrier 1 are enclosed by the housing frame 10G such that all side surfaces of the subsections are covered, in particular completely covered, by the material of the housing frame 10G. The front side 1V and the rear side 1R of the carrier 1 may be free from being covered by the material of the housing frame 10G. Deviating from FIG. 2A, it is possible that the rear side 1R of the carrier 1 is partially or completely covered by the material of the housing frame 10G. It is also possible that the front side 1V of the carrier 1 is partially covered by the material of the housing frame 10G. This is shown schematically, for example, in FIGS. 2B and 2C, in which the first subsection 11 and the second subsection 12 are partially covered by the material of the housing frame 10G and partially not covered, respectively, in a top view of the carrier 1.

The housing 10 of the optoelectronic component 100 has a cavity 3 on its front side 10V. The cavity 3 is formed as a recess in the housing frame 10G. At the front side 10V of the housing 10, the cavity 3 has, for example, a circular disk-shaped cross-section, a rectangular cross-section or another cross-section. In the sectional view of the carrier 1, the cavity 3 tapers from the front side 10V toward the rear side 10R of the housing 10.

The cavity 3 of the housing 10 of the optoelectronic component 100 has a bottom surface 3B and a circumferential lateral wall 3W. The wall 3W is formed by the material of the housing frame 10G. The wall 3W forms a lateral surface of the cavity 3. The wall 3W of the cavity 3 of the housing 10 may form a reflector of the optoelectronic component 100. The lateral surface 3W or the wall of the cavity 3 may be coated with the reflective coating 4. The bottom surface 3B of the cavity 3 may be formed by the front side of the carrier 1, that is, by surfaces of the subsections 11 and 12. In particular, the mounting surface 1M is defined by the bottom surface 3B. The cavity 3 is also filled with the encapsulation 3M.

The arrangement of the reflective coating 4, the barrier layer 5, the bonding layer 6, the component part 2 or 2B, the corrosion protection layer 7, the connection structure 8 and the encapsulation 3M according to FIG. 2A is in particular analogous to the arrangement described in FIG. 1A. In this respect, the features disclosed in connection with FIG. 1A may also be used for the arrangement disclosed in FIG. 2A.

As a difference to FIG. 1A, the barrier layer 5 may partially or completely cover the lateral surface 3W of the cavity 3 and/or the front side 10V. Also, the corrosion protection layer 7 may partially or completely cover the lateral surface 3W of the cavity 3 and/or the front side 10V. Unlike a thiolate coating, direct coverage of the lateral surface 3W by thiolate is not readily possible because the lateral surface 3W is a surface of the electrically insulating housing frame 10G and the thiolate coating generally requires a metal surface.

The exemplary embodiment illustrated in FIG. 2B is substantially the same as the exemplary embodiment of a component 100 illustrated in FIG. 2A. In contrast, the electrical contacting of the component part 2 or 2B is carried out according to the exemplary embodiment illustrated in FIG. 1B, namely via a bonding wire 82 and a rear-side connection column 81. With respect to the electrical contacting of the component part 2 or 2B, the features disclosed in connection with FIG. 1B can therefore also be used for the exemplary embodiment illustrated in FIG. 2B.

As a further difference from FIG. 2A, the front side 1V of the carrier 1 shown in FIG. 2B has subregions which, in top view, are covered by the housing frame 10G. Thus, the reflective coating 4 is also partially covered by the housing frame 10G when viewed from above onto the carrier 1. According to FIG. 2B, the reflective coating 4 can be applied to the carrier 1, in particular to the mounting surface 1M of the carrier 1, before the forming of the housing frame 10G. In contrast, the reflective coating 4 shown in FIG. 2A may be applied to the carrier 1 prior to or after the forming of the housing frame.

In the exemplary embodiment shown in FIG. 2C, the barrier layer 5 may be electrically conductive. For example, the barrier layer 5 is formed from a transparent electrically conductive material. In contrast to the exemplary embodiments shown in FIGS. 2A and 2B, the barrier layer 5 is not formed contiguously, but has at least two subregions 51 and 52 that are laterally separated from each other and thus spatially and electrically separated. The subregions 51 and 52 of the barrier layer 5 are electrically conductively connected, in particular directly electrically conductively connected, to the subregions 41 and 42 of the reflective coating 4, respectively.

The connection structures 8 end on the respective subregions 51 and 52 of the barrier layer 5. The rear-side connection 81 and the bonding wire 82 in particular do not extend throughout the barrier layer 5, but end on the barrier layer 5. The bonding layer 6 can be filled with electrically and thermally conductive particles 6L. In an intermediate region between the partial layers 51 and 52 of the barrier layer 5 and in an intermediate region between the partial layers 41 and 42 of the reflective coating 4, respectively, the corrosion protection layer 7 can extend along the vertical direction throughout the barrier layer 5 and/or the reflective coating 4.

According to one exemplary embodiment, for the electrical contacting of the component part 2 or 2B, the features disclosed in connection with FIG. 1C may also be used for the exemplary embodiment shown in FIG. 2C. In this case, in addition to the bonding wire 82, a rear-side connection column 81 is used for contacting.

The exemplary embodiment shown in FIG. 2D substantially corresponds to the exemplary embodiment of a component 100 shown in FIG. 2C. In contrast thereto, the electrically conductive barrier layer 5 encloses the carrier 1 including the reflective coating circumferentially, i.e. completely. With regard to the electrical contacting of the component part 2 or 2B, the features disclosed in connection with FIG. 2C can therefore also be used for the exemplary embodiment shown in FIG. 2D.

The exemplary embodiment illustrated in FIG. 3 substantially corresponds to the exemplary embodiment of a component 100 illustrated in FIG. 1A. In contrast thereto, it is schematically illustrated that the component 100 may comprise a further component part 2B in addition to a component part 2. In particular, the component part 2 may be electrically conductively connected to the further component part 2B. The component part 2 may be an optoelectronic semiconductor chip configured to generate electromagnetic radiation during operation of the component 100. The further component part 2B may be a protection diode, a further optoelectronic semiconductor chip or an integrated circuit chip. Deviating from FIG. 3, the component 100 may comprise a plurality of such component parts 2 and/or a plurality of such further component parts 2B.

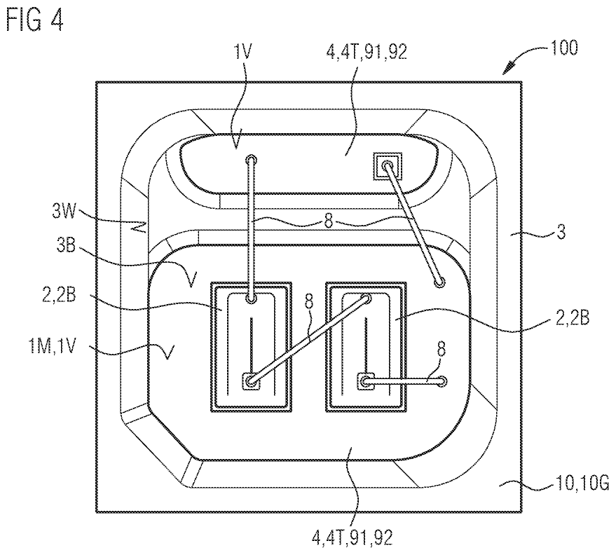

The schematically illustrated exemplary embodiment shown in FIG. 4 may be substantially the same as the top view exemplary embodiment of a component 100 shown in FIG. 2A, 2B, 2C or 2D. Referring to FIG. 4, it is schematically shown that the reflective coating 4 may have a plurality of spatially separated subregions 4T. The component 100 may further comprise a plurality of component parts 2 and/or further component parts 2B.

The invention is not restricted to the exemplary embodiments by the description of the invention made with reference to exemplary embodiments. The invention rather comprises any novel feature and any combination of features, including in particular any combination of features in the claims, even if this feature or this combination is not itself explicitly indicated in the claims or exemplary embodiments.

1.-20. (canceled)

21. An optoelectronic component comprising:
a carrier having a mounting surface comprising a reflective coating;
a semiconductor chip arranged on the carrier; and
a corrosion protection layer located on the semiconductor chip, the semiconductor chip being arranged in a vertical direction between the reflective coating and the corrosion protection layer,
wherein the reflective coating comprises a barrier layer disposed in the vertical direction in places between the semiconductor chip and the reflective coating,
wherein the barrier layer comprises an inorganic material and serves as an additional corrosion protection layer for the reflective coating,
wherein the barrier layer has a vertical layer thickness between 1 nm and 100 nm, inclusive, and
wherein the corrosion protection layer has a vertical layer thickness between 10 nm and 5000 nm, inclusive.

22. The optoelectronic component according to claim 21, wherein the barrier layer has a three-dimensional network structure and is an independent layer.

23. The optoelectronic component according to claim 21, wherein the inorganic material of the barrier layer is an oxide, nitride, oxynitride or a fluoride material.

24. The optoelectronic component according to claim 21, wherein the inorganic material of the barrier layer is a siloxane-based, polysiloxane-based or a polysiloxane-type material.

25. The optoelectronic component according to claim 21, wherein the inorganic material of the barrier layer is a radiation-transmissive and electrically conductive material.

26. The optoelectronic component according to claim 21, wherein the barrier layer is an electrically insulating layer.

27. The optoelectronic component according to claim 21, wherein the vertical layer thickness of the barrier layer is between 1 nm and 50 nm, inclusive, and wherein the vertical layer thickness of the corrosion protection layer is between 10 nm and 1000 nm, inclusive.

28. The optoelectronic component according to claim 21, wherein the semiconductor chip is electrically conductively connected to the carrier via at least one electrical connection structure, the electrical connection structure extending along the vertical direction throughout the barrier layer to the mounting surface.

29. The optoelectronic component according to claim 21,
wherein the carrier is part of a housing and is laterally enclosed by a non-metallic housing frame,
wherein the housing frame comprises a cavity,
wherein the semiconductor chip is arranged on a bottom surface of the cavity, and
wherein the cavity has a circumferential lateral surface which is covered by the barrier layer.

30. The optoelectronic component according to claim 21, wherein the semiconductor chip is a volume emitter.

31. The optoelectronic component according to claim 21, wherein the semiconductor chip is mounted on the barrier layer by a bonding layer, and wherein the bonding layer comprises reflective particles, thermally conductive particles or electrically conductive particles.

32. The optoelectronic component according to claim 21, wherein the corrosion protection layer and the barrier layer are formed from the same material.

33. The optoelectronic component according to claim 21,
wherein the reflective coating is a silver coating,
wherein the semiconductor chip is a volume emitter fixed to the barrier layer by a bonding layer,
wherein the bonding layer comprises an adhesive matrix material configured to reflect electromagnetic radiation emitted from the semiconductor chip,
wherein the barrier layer is electrically insulating,
wherein the semiconductor chip is electrically conductively connected to the carrier via electrical connection structures,
wherein the electrical connection structures extend along the vertical direction throughout the barrier layer and directly adjoin the barrier layer.

34. The optoelectronic component according to claim 21, further comprising:
an electronic component part electrically conductively connected to the semiconductor chip and arranged on the barrier layer,
wherein, in top view, the component part is completely covered by the corrosion protection layer, and
wherein the component part is a further optoelectronic semiconductor chip, an ESD chip or an IC chip.

35. A light source comprising:
the optoelectronic component according to claim 21,
wherein the semiconductor chip is configured to generate electromagnetic radiation in a visible spectral range, an infrared spectral range or an ultraviolet spectral range.

36. A method for producing an optoelectronic component, the method comprising:
providing a carrier having a mounting surface comprising a reflective coating;
applying a barrier layer to the reflective coating, the barrier layer being formed from an inorganic material and serving as an additional corrosion protection layer for the reflective coating;
attaching a semiconductor chip on the carrier; and
applying a corrosion protection layer to the semiconductor chip,
wherein the semiconductor chip is arranged in a vertical direction between the reflective coating and the corrosion protection layer,
wherein the barrier layer is arranged in the vertical direction in places between the semiconductor chip and the reflective coating,
wherein the barrier layer has a vertical layer thickness between 1 nm and 100 nm, inclusive, and
wherein the corrosion protection layer has a vertical layer thickness between 10 nm and 5000 nm, inclusive.

37. The method according to claim 36, wherein applying the barrier layer to the reflective coating comprises apply by atomic layer deposition or by a coating process before the semiconductor chip is attached so that the barrier layer is formed as an independent layer on the reflective coating.

38. The method according to claim 36, wherein the barrier layer is formed in a structured manner such that the reflective coating has subregions which, in top view, are not covered by the barrier layer, and wherein the semiconductor chip is electrically conductively connected to the carrier at the non-covered subregions.

39. The method according to claim 36, wherein the carrier is formed as part of a housing and is laterally enclosed by a non-metallic housing frame, wherein the housing frame is formed by a casting process or by a plastic casting process and has a cavity for receiving the semiconductor chip, and wherein the barrier layer is applied to the reflective coating and to a circumferential lateral surface of the cavity after the housing frame is formed so that the lateral surface is covered by the barrier layer.

40. The method according to claim 36, wherein the carrier is embodied as part of a housing and is laterally enclosed by a non-metallic housing frame, wherein the housing frame is formed by a casting process or a plastic casting process, and wherein the barrier layer is applied to the reflective coating before the housing frame is formed, so that the barrier layer is enclosed by the housing frame in places after the housing frame is formed.
